(19) United States
(12) Patent Application Publication
(10) Pub. No.: US 2023/0253255 A1
(43) Pub. Date: Aug. 10, 2023

(54) MANUFACTURING METHOD FOR SEMICONDUCTOR STRUCTURE AND SEMICONDUCTOR STRUCTURE

(71) Applicant: CHANGXIN MEMORY TECHNOLOGIES, INC., Hefei City, Anhui (CN)

(72) Inventor: Qiang LONG, Hefei City, Anhui (CN)

(73) Assignee: CHANGXIN MEMORY TECHNOLOGIES, INC., Hefei City, Anhui (CN)

(21) Appl. No.: 17/612,995

(22) PCT Filed: Jun. 30, 2021
(86) PCT No.: PCT/CN2021/103852

§ 371 Date: Nov. 19, 2021

(30) Foreign Application Priority Data
Oct. 28, 2020 (CN) 202011173548.8

(51) Int. Cl. H01L 21/8234; H01L 21/768

(52) U.S. Cl. CPC H01L 21/823456; H01L 21/76877; H01L 21/76852

(57) ABSTRACT

A manufacturing method for a semiconductor structure includes: providing a substrate, where the substrate includes an array area and a peripheral area; the array area is provided with active area and first isolation structures; the peripheral area is provided with second isolation structures; and forming gate structures in the array area, and simultaneously forming resistor structures in the second isolation structures of the peripheral area by the step of forming the gate structures.

### CROSS-REFERENCE TO RELATED APPLICATIONS

The present application claims priority to Chinese Patent Application No. 202011173548.8, entitled “MANUFACTURING METHOD FOR SEMICONDUCTOR STRUCTURE AND SEMICONDUCTOR STRUCTURE”, filed on Oct. 28, 2020, which is incorporated herein by reference in its entirety.

### TECHNICAL FIELD

The present disclosure relates to, but is not limited to, a manufacturing method for semiconductor structure and a semiconductor structure.

### BACKGROUND

In a semiconductor structure, a memory is a memory component for storing programs and various data information. A random access memory (RAM) is divided into static random access memory (SRAM) and dynamic random access memory (DRAM). The manufacture and design of the DRAM often involve resistor structures, such as a dropping or current-limiting resistor used in the circuit, a sampling resistor used in the voltage stabilizing circuit or a timing resistor used in the delay circuit.

In order to obtain the resistor structures required by the circuit, a doped polysilicon layer is usually formed on the surface of the substrate of the semiconductor structure. However, this method is complicated, and the manufactured resistor structures occupies a large space, which increases the production cost of the semiconductor structure.

### SUMMARY

An overview of the subject matter detailed in the present disclosure is provided below, which is not intended to limit the protection scope of the claims.

Embodiments of the present disclosure provide a manufacturing method for semiconductor structure and a semiconductor structure, which solve the problems of the resistor structures, such as a complicated manufacturing process, a large space occupied and a high production cost.

A first aspect of the present disclosure provides a manufacturing method for semiconductor structure. The manufacturing method includes: providing a substrate, wherein the substrate includes an array area and a peripheral area; the array area is provided with active area and first isolation structures; the peripheral area is provided with second isolation structures; and forming gate structures in the array area, and simultaneously forming resistor structures in the second isolation structures of the peripheral area by the step of forming the gate structures.

A second aspect of the present disclosure provides a semiconductor structure. The semiconductor structure includes: a substrate, the substrate including an array area and a peripheral area; first isolation structures and active area, the first isolation structures and the active area both being located in the array area; second isolation structures located in the peripheral area; gate structures located in the array area; and resistor structures located in the second isolation structures of the peripheral area.

The embodiments of the present disclosure form resistor structures in the second isolation structures of the peripheral area by the step of forming the gate structures. The embodiments of the present disclosure form the resistor structures by the original step of forming the gate structures, which simplifies the manufacturing step and reduces the manufacturing difficulty. In addition, compared to the resistor structures located on the surface of the substrate, the resistor structures in the present disclosure is located in the space of the original second isolation structures, which saves more space and reduces the production cost.

Other aspects of the present disclosure are understandable upon reading and understanding the drawings and detailed description.

### BRIEF DESCRIPTION OF THE DRAWINGS

The drawings incorporated into the specification and constituting part of the specification illustrate the embodiments of the present disclosure, and are used together with the description to explain the principles of the embodiments of the present disclosure. In these drawings, similar reference numerals are used to represent similar elements. The drawings in the following description are a part rather than all of the embodiments of the present disclosure. Those skilled in the art may derive other drawings based on these drawings without creative efforts.

FIG. 1 is a view illustrating a semiconductor structure.

FIG. 2 is a top view of a semiconductor structure according to an embodiment of the present disclosure.

FIG. 3 is a view illustrating a structure of a substrate used by a manufacturing method for semiconductor structure according to an embodiment of the present disclosure.

FIGS. 4 to 6 are views illustrating structures obtained by implementing various steps of forming first trenches and second trenches by the manufacturing second method of a semiconductor structure according to the embodiment of the present disclosure.

FIG. 7 is a view illustrating a structure obtained by implementing steps of forming an initial oxide layer, an initial barrier layer and an initial conductive layer by the manufacturing method for semiconductor structure according to the embodiment of the present disclosure.

FIG. 8 is a view illustrating a structure obtained by implementing steps of forming an oxide layer, a barrier layer and a conductive layer by the manufacturing method for semiconductor structure according to the embodiment of the present disclosure.

FIG. 9 is a view illustrating a structure obtained by implementing a step of forming an insulating layer by the manufacturing method for semiconductor structure according to the embodiment of the present disclosure.

### REFERENCE NUMERALS

100. substrate; 110. array area; 120. peripheral area; 200. resistor structure; 300. oxide layer; 400. gate structure; 410. barrier layer; 420. conductive layer; 500. first isolation structure; 600. second isolation structure; 700. insulating layer; 800. active area;

10. substrate; 11. array area; 12. peripheral area; 21. first isolation structure; 22. second isolation structure; 31. gate structure; 32. resistor structure; 41. first trench; 42. second trench; 51a. mask layer; 51. patterned mask layer; 52. patterned lithography layer; 61a. initial oxide layer; 61. oxide layer; 62a. initial barrier layer; 62. barrier layer; 621. first barrier layer; 622. second barrier layer; 63a. initial conductive layer; 63. conductive layer; 631. first conductive layer; 632. second conductive layer; 71. insulating layer; 80. active area.

### DETAILED DESCRIPTION

The technical solutions in embodiments of the present disclosure are described below clearly and completely with reference to the drawings in the embodiments of the present disclosure. Apparently, the described embodiments are merely part rather than all of the embodiments of the present disclosure. All other embodiments obtained by those skilled in the art based on the embodiments of the present disclosure without creative efforts should fall within the protection scope of the present disclosure. It should be noted that the embodiments in the present disclosure and features in the embodiments may be combined with each other in a non-conflicting manner.

As mentioned in the background, the resistor structures in the related art have problems such as a complicated manufacturing process, a large space occupied and a high production cost.

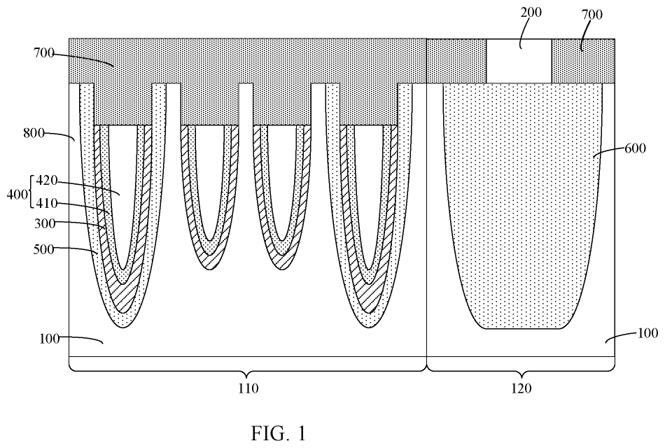

FIG. 1 is a view illustrating a semiconductor structure in the related art. Referring to FIG. 1, a substrate 100 includes an array area 110 and a peripheral area 120. First isolation structures 500 and active area 800 are provided in the array area 110. The active area 800 and the first isolation structures 500 are provided with gate structures 400 and an oxide layer 300. The gate structures 400 each includes a barrier layer 410 and a conductive layer 420. Second isolation structures 600 are provided in the peripheral area 120. An insulating layer 700 is provided on a surface of the substrate 100. The surface of the substrate 100 in the peripheral area 120 is further provided with resistor structures 200.

The resistor structures 200 can only be manufactured after the gate structures 400 and the oxide layer 300 in the array area 110 are manufactured. The whole manufacturing process involves many steps and is complicated. In addition, the resistor structures 200 are usually formed on the surface of the substrate 100, which occupy a large space, and the space in the second isolation structures 600 is not fully utilized, which leads to a high production cost.

An embodiment of the present disclosure provides a manufacturing method for semiconductor structure. The manufacturing method includes: simultaneously form resistor structures in second isolation structures of a peripheral area by the step of forming gate structures. The embodiment of the present disclosure forms the resistor structures by the original step of forming the gate structures, which simplifies the manufacturing step and reduces the manufacturing difficulty. In addition, since the resistor structures are formed in the second isolation structures, the space in the second isolation structures is fully utilized, which reduces the space occupied by the resistor and reduces the production cost.

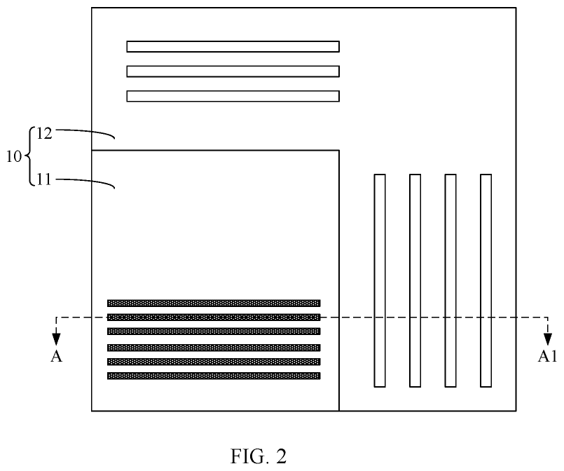

A first embodiment of the present disclosure provides a manufacturing method for semiconductor structure. FIGS. 2 to 9 illustrate structures obtained by implementing various steps of the manufacturing method for semiconductor structure in this embodiment.

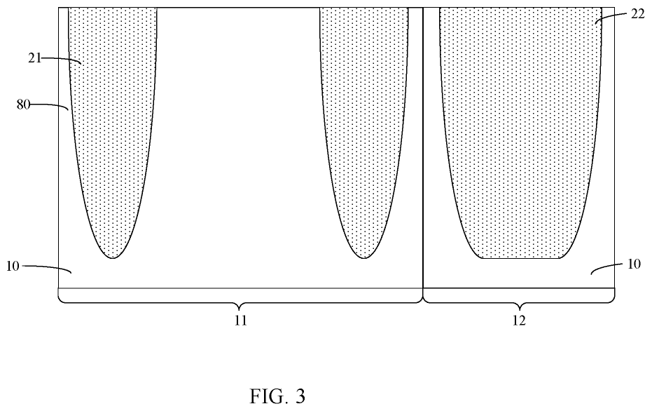

Referring to FIGS. 2 and 3, FIG. 2 is a top view of the semiconductor structure in this embodiment, and FIG. 3 is a cross-sectional view taken along A-A1 direction shown in FIG. 2. A substrate 10 is provided. The substrate 10 includes an array area 11 and a peripheral area 12. The array area 11 is provided with active area (AA) 80 and first isolation structures 21. The peripheral area 12 is provided with second isolation structures 22. In this embodiment, the semiconductor structure is a memory. The array area 11 is correspondingly an area of forming an array of the active area 80 of the memory, and the peripheral area 12 is correspondingly an area of forming a peripheral device of the memory, such as a logic control circuit.

In this embodiment, the surface of the substrate 10 may also be used to form resistor structures, other logic control device or array device used in a circuit. The surface and internal space of the substrate 10 can be utilized, which improves the space utilization of the semiconductor structure.

The substrate 10 has multiple active areas 80, and the first isolation structures 21 are configured to isolate adjacent active areas 80 in the array area 11.

In this embodiment, the first isolation structures 21 and the second isolation structures 22 are shallow trench isolation (STI) structures.

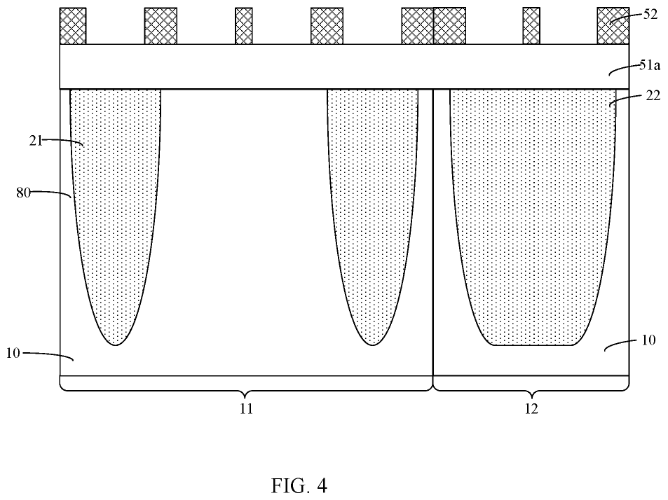

Referring to FIGS. 4 to 9, gate structures 31 are formed in the array area 11, and by the step of forming the gate structures 31, resistor structures 32 are formed in the second isolation structures 22 of the peripheral area 12 simultaneously.

The resistor structures 32 are formed in the second isolation structures 22 by the manufacturing step and a photomask required for forming the gate structures 31, which simplifies the production process and reduces the production difficulty and cost. In addition, the resistor structures 32 utilize the space of the original second isolation structures 22, which improves the space utilization, thereby reducing the size of the semiconductor structure and reducing the production cost.

The gate structures 31 are located in the active area 80 and the first isolation structures 21 of the array area 11.

The gate structures 31 and the resistor structures 32 are formed as follows:

Referring to FIGS. 4 to 6, first trenches 41 are formed in the array area 11 while second trenches 42 are formed in the second isolation structures 22 of the peripheral area 12.

The first trenches 41 serve as filling space to form the gate structures later, and the second trenches 42 serve as filling space to form the resistor structures later.

The first trenches 41 are located in the active area 80 and the first isolation structures 21 of the array area 11. The cross-sectional shape of the first trenches 41 or the second trenches 42 includes a square shape or a U shape.

In this embodiment, there are two second trenches 42 located in the same second isolation structure 22. In other embodiments, there may be one, three or more than three second trenches in the same second isolation structure, and the number of the second trenches may be designed according to actual needs.

In order to form resistor structures of different volumes, the opening widths and depths of the multiple second trenches 42 located in the same second isolation structure 22 may be different, and the opening widths and depths of the multiple second trenches 42 located in different second isolation structures 22 may also be different.

The depth of each of the second trenches 42 is smaller than that of the second isolation structures 22. In this way, the second isolation structures 22 can cover the bottom of the resistor structures formed subsequently, so as to avoid problems such as leakage and interference of the resistor structures, thereby improving the stability of the resistor structures and other structures in the circuit.

It is understandable that the depth of the first trenches 41 located in the first isolation structures 21 is smaller than that of the first isolation structures 21.

The first trenches 41 and the second trenches 42 are formed as follows:

Referring to FIG. 4, a mask layer 51a and a patterned lithography layer 52 are sequentially deposited on the substrate 10.

In this embodiment, the material of the mask layer 51a includes silicon nitride, silicon oxynitride or silicon carbide, etc. In this embodiment, the mask layer 51a has a single-layer structure. In other embodiments, the mask layer may also have a multi-layer structure.

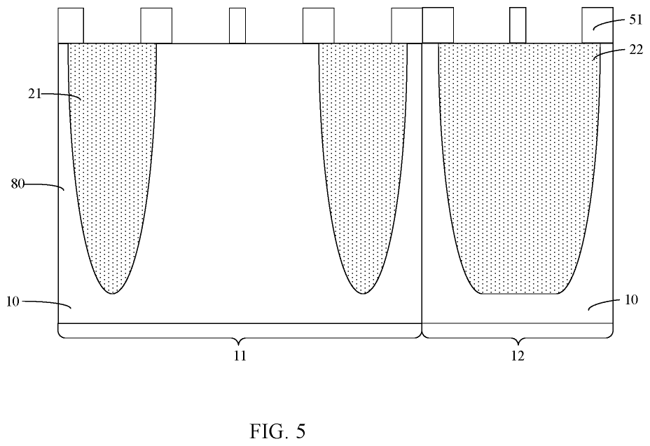

Referring to FIG. 5, the mask layer 51a is etched by taking the patterned lithography layer 52 (shown in FIG. 4) as a mask, and a patterned mask layer 51 is formed.

In this embodiment, after the patterned mask layer 51 is formed, the patterned lithography layer 52 is removed.

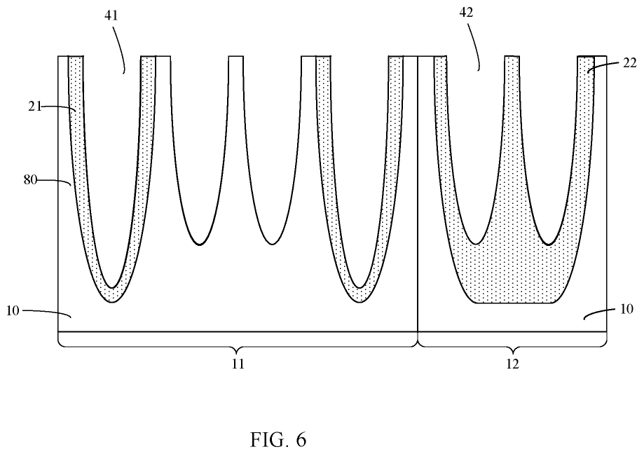

Referring to FIG. 6, the substrate 10 is etched by taking the patterned mask layer 51 (shown in FIG. 5) as a mask, and the first trenches 41 and the second trenches 42 are formed.

In this embodiment, after the first trenches 41 and the second trenches 42 are formed, the patterned mask layer 51 is removed.

In this embodiment, only one patterned mask layer 51 is configured to form the first trenches 41 and the second trenches 42. In other embodiments, a double patterning process may also be used to form the first trenches and the second trenches. Alternatively, in other embodiments, there may be no need to form a patterned mask layer. Instead, a patterned lithography layer is directly formed on the surface of the substrate, and the patterned lithography layer is used as a mask to etch the substrate to form the first trenches and the second trenches.

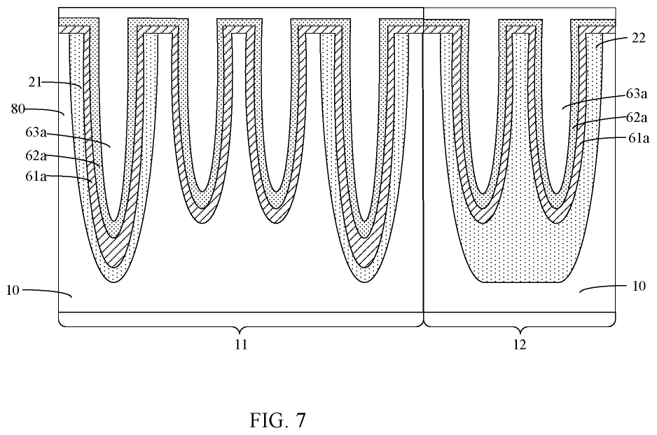

Referring to FIG. 7, an initial oxide layer 61a is formed on sidewalls and a bottom of each of the first trenches 41 (shown in FIG. 6) and the second trenches 42 (shown in FIG. 6). The initial oxide layer 61a also covers the surface of the substrate 10. An initial barrier layer 62a is formed on a surface of the initial oxide layer 61a.

In this embodiment, the initial oxide layer 61a is made of silicon oxide. In other embodiments, the material of the initial oxide layer may also have a high dielectric constant. Generally, a chemical vapor deposition (CVD) process or an atomic layer deposition (ALD) process is used to form the initial oxide layer 61a.

In this embodiment, the initial barrier layer 62a is made of titanium nitride. In other embodiments, the material of the initial barrier layer may also include tantalum nitride, etc. The initial barrier layer 62a may be formed by a CVD process or an ALD process.

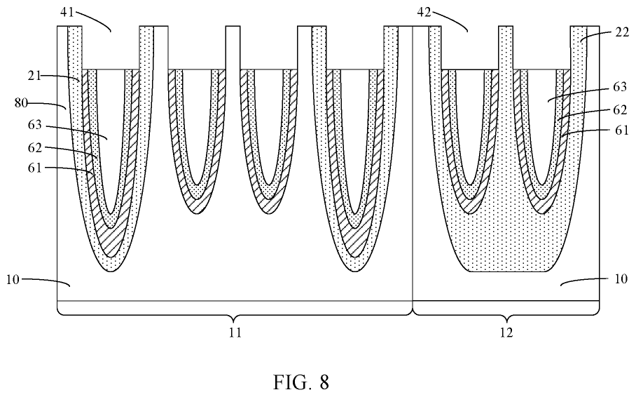

Referring to FIGS. 7 and 8, an conductive layer 63 is deposited in the first trenches 41 and the second trenches 42. The conductive layer 63 located in the first trenches 41 is configured to form the gate structures, and the conductive layer 63 located in the second trenches 42 is configured to form the resistor structures.

Referring to FIG. 7, an initial conductive layer 63a is deposited on the initial barrier layer 62a. The initial conductive layer 63a covers a surface of the initial barrier layer 62a and fills the first trenches 41 (shown in FIG. 6) and the second trenches 42 (shown in FIG. 6).

Referring to FIG. 8, part of the initial conductive layer 63a (shown in FIG. 7), part of the initial barrier layer 62a (shown in FIG. 7) and part of the initial oxide layer 61a (shown in FIG. 7) are removed to form a barrier layer 63, an oxide layer 62 and the conductive layer 61, the barrier layer, the oxide layer and the conductive layer are lower than the surface of the substrate 10.

In this embodiment, part of the initial conductive layer 63a, part of the initial barrier layer 62a and part of the initial oxide layer 61a that are higher than the substrate 10 are removed by a chemical mechanical polishing (CMP) process. Part of the initial conductive layer 63a, part of the initial barrier layer 62a and part of the initial oxide layer 61a which are located in the substrate 10 are etched back to form the conductive layer 63, the barrier layer 62 and the oxide layer 61. The conductive layer 63 is located on the barrier layer 62, and the barrier layer 62 is located on the oxide layer 61.

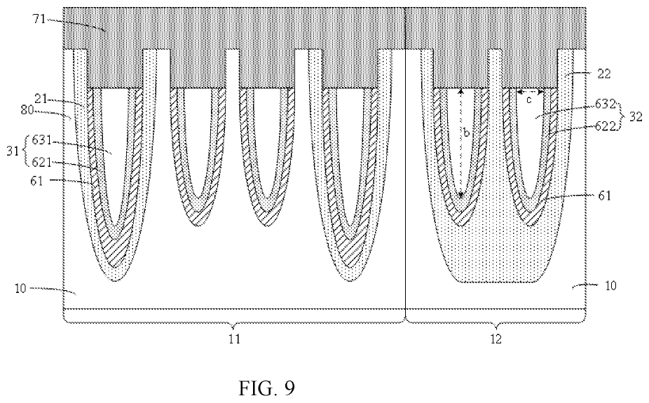

In some embodiments, referring to FIG. 9, the barrier layer 62 (shown in FIG. 8) includes first barrier layer 621 and second barrier layer 622. The first barrier layer 621 is located in the array area 11, and the second barrier layer 622 is located in the peripheral area 12.

The conductive layer 63 (shown in FIG. 8) includes first conductive layer 631 and second conductive layer 632. The first conductive layer 631 is located in the array area 11, and the second conductive layer 632 is located in the peripheral area 12.

In this embodiment, since the first conductive layer 631 and the second conductive layer 632 are formed in the same manufacturing step, the second conductive layer 632 and the first conductive layer 631 may be made of the same material, which may be tungsten or titanium.

In other embodiments, the material of the first conductive layer and the second conductive layer may also be polysilicon or doped polysilicon.

A first barrier layer 621 and a first conductive layer 631 constitute a gate structure 31. The first barrier layer 621 can prevent the material of the first conductive layer 631 from diffusing into the oxide layer 61, thereby ensuring the stability of the semiconductor device.

A second barrier layer 622 and a second conductive layer 632 constitute a resistor structure 32. The second barrier layer 622 can prevent the material of the second conductive layer 632 from diffusing into the second isolation structure 22, thereby improving the stability of the resistor structure 32.

The manufacturing method further includes: form an insulating layer 71 on surfaces of the gate structures 31, surfaces of the resistor structures 32 and the surface of the substrate 10, so as to prevent the gate structures 31 from being oxidized in a subsequent process.

The insulating layer 71 may be subsequently etched to form through holes exposing the resistor structures 32. A conductive material is filled in the through holes to realize the electrical connection between the resistor structure 32 and other structure or circuit.

It is understandable that the insulating layer 71 may be etched subsequently to form recesses in the insulating layer 71. A conductive material is filled in the recesses to form surface resistor structures located on the surface of the substrate 10. In addition, other logic control device or array device may also be formed in the recesses. The surface and internal space of the substrate 10 can be utilized, which improves the space utilization of the semiconductor structure and reduces the size of the semiconductor structure.

In summary, in this embodiment, the resistor structures 32 and the gate structures 31 are formed in the same manufacturing step, which simplifies the production process and reduces the production cost. In addition, the resistor structures 32 are located in the second isolation structures 22, which saves the space, reduces the size of the semiconductor structure, and reduces the production cost.

A second embodiment of the present disclosure provides a semiconductor structure. The semiconductor structure may be manufactured by the manufacturing method for semiconductor structure provided in the first embodiment.

Referring to FIG. 9, the semiconductor structure includes: a substrate 10, the substrate including an array area 11 and a peripheral area 12; first isolation structures 21 and active area 80 which are located in the array area 11; second isolation structures 22 located in the peripheral area 12; gate structures 31 located in the array area 11; and resistor structures 32 located in the second isolation structures 22 of the peripheral area 12.

The gate structures 31 are located in the active area 80 and the first isolation structures 21 of the array area 11.

At least one resistor structures 32 is provided in the same second isolation structure 22. Multiple resistor structures 32 may have different volumes, widths c and thicknesses b. It is understandable that multiple resistor structures 32 in different second isolation structures 22 may also have different volumes, different widths c and different thicknesses b. In this way, the requirements of the circuit for different resistor structures 32 can be met.

The gate structures 31 each includes a first barrier layer 621 and a first conductive layer 631, and the first conductive layer 631 covers a surface of the first barrier layer 621. The resistor structures 32 each includes a second conductive layer 632 and a second barrier layer 622, and the second conductive layer 632 covers a surface of the second barrier layer 622. That is, in the gate structure 31, the first conductive layer 631 is located on the first barrier layer 621, and in the resistor structure 32, the second conductive layer 632 is located on the second barrier layer 622.

The resistor structures 32 and the gate structures 31 are made of the same material. For example, the first conductive layer 631 and the second conductive layer 632 are made of tungsten or titanium, and the first barrier layer 621 and the second barrier layer 622 are made of titanium nitride or tantalum nitride.

The semiconductor structure provided in this embodiment further includes an insulating layer 71. The insulating layer 71 covers surfaces of resistor structures 32, surfaces of the gate structures 31 and surfaces of the substrate 10. The insulating layer 71 can protect the resistor structures 32 and the gate structures 31 from being oxidized.

The semiconductor structure provided in this embodiment further includes oxide layer 61. The oxide layer 61 is located in the substrate 10. The gate structures 31 and the resistor structures 32 cover the surface of the oxide layer 61, that is, the gate structures 31 and the resistor structures 32 are located on the oxide layer 61.

In summary, the resistor structures 32 are located in the second isolation structures 22, which saves the space and reduces the size of the semiconductor structure. In addition, the volumes of resistor structures 32 located in the same second isolation structure 22 may be different to meet the requirements of the circuit for different resistor structures 32.

Each embodiment in the specification of the present disclosure is described in a progressive manner. Each embodiment focuses on the difference from other embodiments, and the same and similar parts between the embodiments may refer to each other.

In the description of the specification, the description with reference to terms such as “an embodiment”, “an illustrative embodiment”, “some implementations”, “an illustrative implementation” and “an example” means that the specific feature, structure, material or feature described in combination with the implementation(s) or example(s) is included in at least one implementation or example of the present disclosure.

In this specification, the schematic expression of the above terms does not necessarily refer to the same implementation or example. Moreover, the described specific feature, structure, material or feature may be combined in an appropriate manner in any one or more implementations or examples.

It should be noted that in the description of the present disclosure, the terms such as “center”, “top”, “bottom”, “left”, “right”, “vertical”, “horizontal”, “inner” and “outer” indicate the orientation or position relationships based on the drawings. These terms are merely intended to facilitate description of the present disclosure and simplify the description, rather than to indicate or imply that the mentioned device or element must have a specific orientation and must be constructed and operated in a specific orientation. Therefore, these terms should not be construed as a limitation to the present disclosure.

It should be understood that the terms such as “first” and “second” used herein may be used to describe various structures, but these structures are not limited by these terms. Instead, these terms are merely intended to distinguish one element from another.

The same elements in one or more drawings are denoted by similar reference numerals. For the sake of clarity, various parts in the drawings are not drawn to scale. In addition, some well-known parts may not be shown. For the sake of brevity, the structure obtained by implementing multiple steps may be shown in one figure. In order to make the understanding of the present disclosure more clearly, many specific details of the present disclosure, such as the structure, material, size, processing process and technology of the device, are described below. However, as those skilled in the art can understand, the present disclosure may not be implemented according to these specific details.

Finally, it should be noted that the above embodiments are merely intended to explain the technical solutions of the present disclosure, rather than to limit the present disclosure. Although the present disclosure is described in detail with reference to the above embodiments, those skilled in the art should understand that they may still modify the technical solutions described in the above embodiments, or make equivalent substitutions of some or all of the technical features recorded therein, without deviating the essence of the corresponding technical solutions from the scope of the technical solutions of the embodiments of the present disclosure.

### INDUSTRIAL APPLICABILITY

The present disclosure provides a manufacturing method for semiconductor structure and a semiconductor structure. The present disclosure simultaneously forms resistor structures in the second isolation structures of the peripheral area by the step of forming gate structures, which simplifies the manufacturing step and reduces the manufacturing difficulty. In addition, since the resistor structures are formed in the second isolation structures, the space in the second isolation structures is fully utilized, which reduces the space occupied by the resistor and reduces the production cost.

What is claimed is:

1. A manufacturing method for semiconductor structure, comprising:
providing a substrate, wherein the substrate comprises an array area and a peripheral area; the array area is provided with active area and first isolation structures; the peripheral area is provided with second isolation structures; and
forming gate structures in the array area, and simultaneously forming resistor structures in the second isolation structures of the peripheral area by the step of forming the gate structures.

2. The manufacturing method for semiconductor structure according to claim 1, wherein the step of forming gate structures and resistor structures comprises:
forming first trenches in the array area while forming second trenches in the second isolation structures of the peripheral area;
depositing a conductive layer in the first trenches and the second trenches, wherein a conductive layer located in the first trenches is configured to form the gate structures, and a conductive layer located in the second trenches is configured to form the resistor structures; and
forming an insulating layer on surfaces of the gate structures, surfaces of the resistor structures and a surface of the substrate.

3. The manufacturing method for semiconductor structure according to claim 2, wherein the step of forming first trenches and second trenches comprises:
sequentially depositing a mask layer and a patterned lithography layer on the substrate;
etching the mask layer by taking the patterned lithography layer as a mask, and forming a patterned mask layer; and
etching the substrate by taking the patterned mask layer as a mask, and forming the first trenches and the second trenches.

4. The manufacturing method for semiconductor structure according to claim 2, wherein the first trenches are located in the active area and the first isolation structures.

5. The manufacturing method for semiconductor structure according to claim 2, wherein before forming a conductive layer, the manufacturing method further comprises:
forming an initial oxide layer on sidewalls and a bottom of each of the first trenches and the second trenches, the initial oxide layer also covering the surface of the substrate; and
forming an initial barrier layer on a surface of the initial oxide layer.

6. The manufacturing method for semiconductor structure according to claim 5, wherein the step of forming a conductive layer comprises:
depositing an initial conductive layer on the initial barrier layer, the initial conductive layer covering a surface of the initial barrier layer and filling the first trenches and the second trenches; and
removing part of the initial conductive layer, part of the initial barrier layer and part of the initial oxide layer to form a barrier layer, an oxide layer and the conductive layer, wherein the barrier layer, the oxide layer and the conductive layer are lower than the surface of the substrate.

7. The manufacturing method for semiconductor structure according to claim 6, wherein the barrier layer comprises a first barrier layer and a second barrier layer; the first barrier layer is located in the array area, and the second barrier layer is located in the peripheral area; the conductive layer comprises a first conductive layer and a second conductive layer; the first conductive layer is located in the array area, and the second conductive layer is located in the peripheral area; a first barrier layer and a first conductive layer constitute a gate structure, and a second barrier layer and a second conductive layer constitute an resistor structure.

8. The manufacturing method for semiconductor structure according to claim 1, wherein the gate structures are located in the active area and the first isolation structures of the array area.

9. The manufacturing method for semiconductor structure according to claim 2, wherein the manufacturing method further comprises:
forming recesses in the insulating layer; and forming surface resistor structures, located on the surface of the substrate, in the recesses.

10. A semiconductor structure, comprising:
a substrate, the substrate comprising an array area and a peripheral area;
first isolation structures and active area, the first isolation structures and the active area both being located in the array area;
second isolation structures located in the peripheral area;
gate structures located in the array area; and
resistor structures located in the second isolation structures of the peripheral area.

11. The semiconductor structure according to claim 10, wherein the gate structures are located in the active area and the first isolation structures of the array area.

12. The semiconductor structure according to claim 10, wherein the gate structures each comprises a first barrier layer and a first conductive layer, and the first conductive layer covers a surface of the first barrier layer; the resistor structures each comprises a second conductive layer and a second barrier layer, and the second conductive layer covers a surface of the second barrier layer.

13. The semiconductor structure according to claim 10, wherein the semiconductor structure further comprises an insulating layer; the insulating layer covers surfaces of the resistor structures, surfaces of the gate structures and a surface of the substrate.

14. The semiconductor structure according to claim 10, wherein the semiconductor structure further comprises oxide layer; the oxide layer is located in the substrate, and the gate structures and the resistor structures cover a surface of the oxide layer.
